(19) United States
(12) Patent Application Publication
(10) Pub. No.: US 2008/0198890 A1
(43) Pub. Date: Aug. 21, 2008

(54) VERTICALLY EMITTING LASER AND METHOD OF MAKING THE SAME

(76) Inventors: Jeffrey E. Ungar, Valley Village, CA (US); Mark L. Osowski, Tujunga, CA (US)

Correspondence Address: JEFFER, MANGELS, BUTLER & MARMARO, LLP, 1900 AVENUE OF THE STARS, 7TH FLOOR, LOS ANGELES, CA, 90067, US

(21) Appl. No.: 11/677,417

(22) Filed: Feb. 21, 2007

(51) Int. Cl. H01S 5/00

(52) U.S. Cl. 372/50.11; 372/50.1

(57) ABSTRACT

Diode lasers comprise a substrate and a number of material layers disposed thereon that include a P-type material layer, and an N-type material layer. A gain layer and diffraction grating feedback layer can be also be included in the material layers. The material layers are formed by epitaxial deposition, during which process a wall surface common to the material layers is also formed. This wall surface forms an internally reflective wall surface within the material layers that is oriented to reflect a laser beam internally within the diode laser construction towards a top or bottom surface of the diode laser for emission therefrom. In an preferred embodiment, the internally reflective wall surface is oriented at a 45 degree angle, and the laser beam is reflected by the wall surface to emit the laser beam from the diode laser at a 90 degree angle relative to the top or bottom surface.

### FIELD OF THE INVENTION

This invention relates to vertically emitting lasers or other types of vertically emitting optical devices such as optical waveguides or the like and, more specifically, to vertically emitting semiconductor lasers or diode lasers that are specially constructed having an internally reflective wall surface that is formed during the process of making the different layers forming the laser, thereby improving both the manufacturing efficiency of making the laser, and the quality of the resulting laser.

### BACKGROUND OF THE INVENTION

Semiconductor lasers, or diode lasers, are known in the art, and are constructed for use in a variety of different types of applications. For example, semiconductor lasers can be used for applications including laser pumping, defense, material processing, medical, scientific, printing and fiber optic communication systems. Semiconductor lasers or diode lasers are specially constructed to emit a desired wavelength laser beam having a desired power output tailored for use in the particular end-use application. Diode lasers can be configured to emit the desired wavelength laser beam from either a side edge of the diode die, i.e., be an edge-emitting laser, or from a top or bottom surface of the die, i.e., be a surface- or substrate-emitting laser, depending on the particular diode laser configuration.

Edge emitting diode lasers known in the art are constructed by first epitaxially depositing the different desired layers of materials upon a crystalline substrate to form a wafer, and subsequently cleaving or cutting this wafer into individual chips or linear arrays (commonly referred to as “bars”). Because the chips and bars typically generate laser beams that propagates parallel to the plane of the wafer, surfaces on the chip or bar that are perpendicular to the wafer plane (“facets”) must be fabricated to provide exit windows for the beam. An additional function of these facets is to create reflective surfaces that form the laser resonant cavity. Suitable coatings are often applied to these facets to modify the reflectivity as may be required for optimum laser performance.

Because edge emitting diodes emit the beam from the edge of the semiconductive die, each die must be individually cut from the wafer, cleaved, and then coated as noted above before being tested. The need to test each individual diode laser at the die level, rather than being able to test multiple diode lasers at a wafer level, adversely impacts the manufacturing efficiency and cost associated with making such conventional edge emitting diode lasers.

An additional limitation arises because the output of each laser bar is very limited (typically to several tens of Watts). If laser beams of higher power are required (as, for example, is typically the case for high power industrial or military lasers) it is necessary to individually cool and collimate a plurality of bars, and then combine their beams with mechanically stacking 10 or 20 laser bars, each bar being mounted on its own micro-channel water cooled heat sink, and each bar provided with its own collimation lens, in order to create a two-dimensional (row and column) array of laser diode emitters. This configuration is costly and difficult to fabricate because of the large number of lenses, coolers and bars. Because the bars are mounted on separate coolers, their beams are not intrinsically collinear, and it is necessary to co-align each of them separately. Finally, micro-channel coolers are subject to corrosion-related failure modes including clogging and leaking, which sharply limit the reliable lifetime of these arrays.

For these reasons, use of such edge emitting lasers known in the art is limited to certain end-use applications, e.g., those not calling for a strong or powerful laser beam and/or those where laser assembly, packaging, size, weight, and/or the cost associated with the same is not a concern, making edge emitting diode lasers unsuited for many important applications calling for high power laser beam output.

Surface emitting diode lasers known in the art are specially configured to facilitate emission of a desired laser beam vertically away from a top or bottom surface of the diode rather than from an edge. Such surface emitting diode lasers known in the art include Vertical Cavity Surface Emitting Lasers (VCSELs) and grating surface emitters. A feature of such known surface emitting diode lasers, such as VCSELs is that they can be formed and tested in wafer form, thereby improving manufacturing efficiency and thereby reducing manufacturing costs.

However, to date, conventional surface emitting diode lasers have not been practical for use in making high power arrays due to issues such as thermal/electrical impedance, and modal instabilities. Accordingly, surface emitting diode lasers known in the literature emit a relatively low power laser beam that has limited their use to low power laser beam applications, making them unsuited for applications calling for high power laser beam output.

Attempts have been made to form a diode laser construction comprising an edge emitting diode laser that has been configured to permit the laser beam produced therein to such example, a plane laser has been coupled to a monolithically-integrated dry etched or ion-milled 45 degree turning mirror. However, such mirrors tend to be optically rough, nonplanar, and inaccurately aligned, thereby impairing the ability to provide a highly focused or collimated laser beam therefrom. Further, the dry etching process is also inherently damaging to the front facet of the semiconductor material, and therefore can significantly reduce the reliability of these devices

Other techniques that have been employed for the purpose of forming such integrated mirror or mirrors for use with diode lasers include wet etching. However, because of the different materials present in the different layers forming the diode laser construction, it has been found that the wet etching solution does not always produce an optically smooth surface along the different layers, which smooth surface is again needed for use in laser beam reflection.

Accordingly, to date there exists a need for a diode laser construction that is capable of providing a desired high power laser beam output within a desired wavelength, having a relatively low thermal and electrical impedance, and capable of being provided in the form of a relatively small, compact, and/or lightweight construction.

It is, therefore, desired that a semiconductor or diode laser construction be provided in a manner that facilitates surface or vertical laser beam emission in a manner that is practical and cost effective from a manufacturing perspective. It is desired that such diode laser construction have good optical properties that facilitate its use in a number of different applications, wherein the diode laser can be used alone or with other such diode lasers provided for example in the form of an array. It is further desired that such diode laser construction be capable of providing a relatively high power laser beam output to facilitate use in end-use applications calling for the same. It is still further desired that such diode laser construction be configured in a manner that provides the above-desired high power laser output laser while also having a relatively compact construction.

### SUMMARY OF THE INVENTION

Semiconductor or diode laser constructions, prepared according to principles of the invention comprise a substrate, preferably one that is formed from a III-V compound. A number of material layers are disposed onto the substrate, and these layers include a P-type material layer, and an N-type material layer. The material layers can additionally include a gain or active layer interposed between the P-type material layer and the N-type material layer. A diffraction grating feedback layer can be included and positioned parallel to the gain or active layer. The diffraction grating feedback layer can include a corrugated section that extends entirely or partially therealong to provide a desired laser beam frequency of oscillation.

The material layers are preferably formed by the epitaxial growth of multiple semiconductor layers oriented parallel to the plane of the substrate. As these layers grow in a direction perpendicular to the substrate plane, a wall surface common to the material layers is also formed and provides an internally reflective surface that operates to reflect a laser beam produced by the diode laser construction in a desired direction. In an example embodiment, the internally reflective wall surface is oriented during the process of it being formed in a manner that operates to reflect the laser beam produced within the diode laser and initially projecting parallel to the substrate plane outwardly and away from a top or bottom surface of the diode laser construction.

When the diode laser construction is configured in the form of a surface emitting diode laser, the material layers and internally reflective wall surface are constructed and oriented in a manner that causes the laser beam produced therein to be reflected through one or more material layers and out of a top surface of the diode laser construction formed from one of the material layers.

When the diode laser construction is configured in the form of a substrate emitting diode laser, the material layers and internally reflective wall surface are constructed and oriented in a manner that causes the laser beam produced therein to be reflected through one or more material layers and the substrate, and out of a bottom surface of substrate.

In an example embodiment, the internally reflective wall surface is oriented at an angle that will cause the laser beam to exit the diode laser at an angle of approximately 90 degrees relative to the top or bottom surface of the diode laser construction. This can be achieved by orienting the internally reflective wall surface at an angle of approximately 45 degrees relative to the direction of the laser beam produced within the construction. In an example embodiment, such desired 45 degree orientation can be achieved by epitaxial growth of the material layer when the substrate is vicinally oriented at an angle of approximately 9.7 degrees from a (100) orientation.

Diode laser constructions configured and formed in this manner facilitate surface or vertical laser beam emission in a manner that avoids the need to cleave, coat, test and perform other costly and/or time-consuming processes at chip or bar level, and instead allows them to be performed at wafer level at much lower cost. Thus, diode laser constructions of this invention are practical and cost effective from a manufacturing perspective when compared to conventional surface or vertical emitting diode lasers. Diode laser constructions of this invention have good optical properties that facilitate their use alone or in combination with other diode lasers in an array. Further, such diode laser constructions are capable of providing a relatively high power laser beam output to facilitate use in applications calling for the same. Still further, such diode laser constructions provide a high power laser output laser while also having a relatively compact construction.

### BRIEF DESCRIPTION OF THE DRAWINGS

FIG. 1 is a side perspective view of an example embodiment semiconductor laser constructed in accordance with principles of this invention;

FIG. 2 is a cross-sectional side view of one example embodiment semiconductor laser constructed in accordance with principles of this invention;

FIG. 3 is a cross-sectional side vide of a second example embodiment semiconductor laser constructed in accordance with principles of this invention;

FIGS. 4A to 4C illustrates an example embodiment semiconductor laser constructed in accordance with principles of this invention at different stages of construction;

FIGS. 5A to 5C illustrates another example embodiment semiconductor laser constructed in accordance with principles of this invention at different stages of construction; and

FIG. 6 illustrates a perspective view of an array of semiconductor lasers constructed in accordance with principles of this invention.

### DETAILED DESCRIPTION

Semiconductor lasers or diode lasers of this invention are specially formed having an internally reflective wall surface that is positioned within the structure of the semiconductor construction to facilitate the emission of a laser beam provided within the construction in a direction that is outwardly away from a top or bottom surface of the diode laser. As discussed in greater detail below, the internally reflective wall can be provided at a particular angle to produce a particular desired angle of emission from a top or bottom surface of the diode laser. In an example embodiment, the diode laser is formed by epitaxial deposition, and the internally reflective wall is formed during such process by the crystallographic selective growth properties of the materials used to form the diode laser.

Because the internally reflective wall is formed in situ during the process of depositing the material layers used to make the diode laser, the need to subsequently form such reflective surface by ion milling, dry or wet etching, or other such technique, and perhaps requiring further processing to smoothen and/or polish the just-formed wall, are all avoided. The process of forming the internal wall by selective deposition as described in greater detail below is one that produces a wall surface that is both accurately located and oriented and that has the desired optical smoothness without the need for subsequent polishing.

The internally reflective wall surface is positioned within the semiconductor construction in a manner that operates to direct radiation produced within the diode laser outwardly from a top or bottom surface of the diode laser. Diode lasers of this invention generally include a gain layer and a diffraction grating feedback layer located within a semiconductive die. If desired, the diffraction grating feedback layer can be optional, e.g., it can be replaced by using a suitable reflective surface formed at an end of diode laser construction. In an example embodiment, the gain and feedback layers are positioned and constructed in a manner that operates to generate a laser beam that travels within an active layer of the semiconductor structure, and that runs generally parallel to the top or bottom surface of the die.

The internally reflective wall surface formed in the semiconductor construction is specially configured and oriented in a manner that is calculated to reflect the laser beam that is produced within the diode so that it emits outwardly from a top or bottom surface of the die. The angle of laser beam emission from the top or bottom surface can vary depending on the particular end-use application, in an example embodiment the laser beam emits at an angle of approximately 90 degrees relative to the surface. The angle of laser beam emission from the diode laser surface is controlled by the orientation of the internally reflective wall surface. As discussed below, in the example embodiment where the laser beam emits at a 90 degree angle, or emits perpendicular to the diode laser surface, the internally reflective wall surface is positioned at an angle of approximately 45 degrees relative to the direction of the laser beam produced within the diode laser.

In an example embodiment, the internally reflective wall surface is formed in situ during the process of making the semiconductor construction by selectively growing the different layers used to make the construction on a specially oriented semiconductor substrate, e.g., a vicinally oriented III-V semiconductor substrate, so that the internally reflective wall surface extends along a desired plane, e.g., the (111)B crystalline plane, of the semiconductor die.

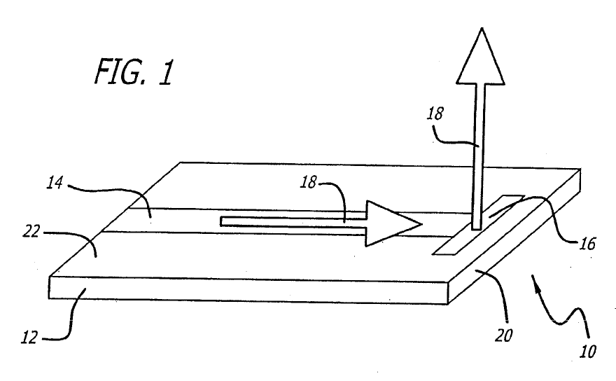

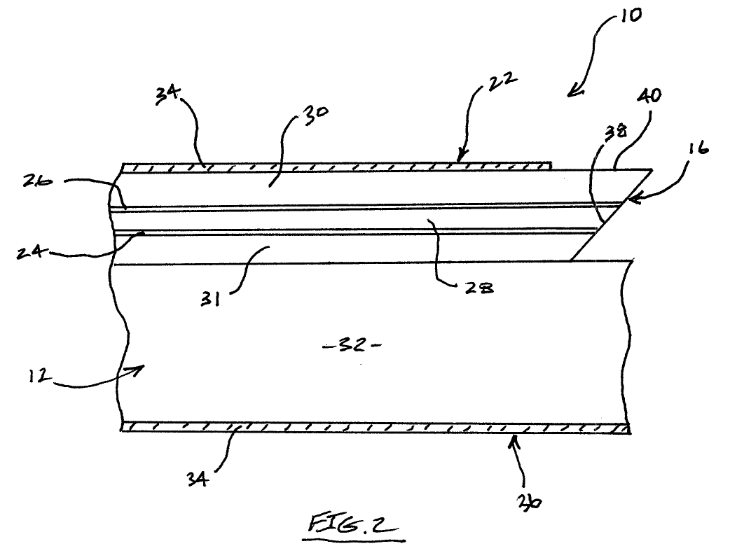

FIG. 1 illustrates an embodiment of the diode laser construction prepared according to principles of this invention, and generally depicts how a laser beam that is produced internally within the diode laser proceeds through the construction to be emitted from a top surface. The example embodiment diode laser illustrated in FIGS. 1 and 2 include an internally reflective wall that is oriented to promote emission of the laser beam from a top surface of the construction. Although not illustrated in FIG. 1, it is to be understood that diode lasers of this invention can be configured having the internally reflective wall surface oriented differently than that illustrated herein in an obvious fashion to facilitate emission of the laser beam through the substrate and outwardly from a bottom surface of the diode laser construction if so desired.

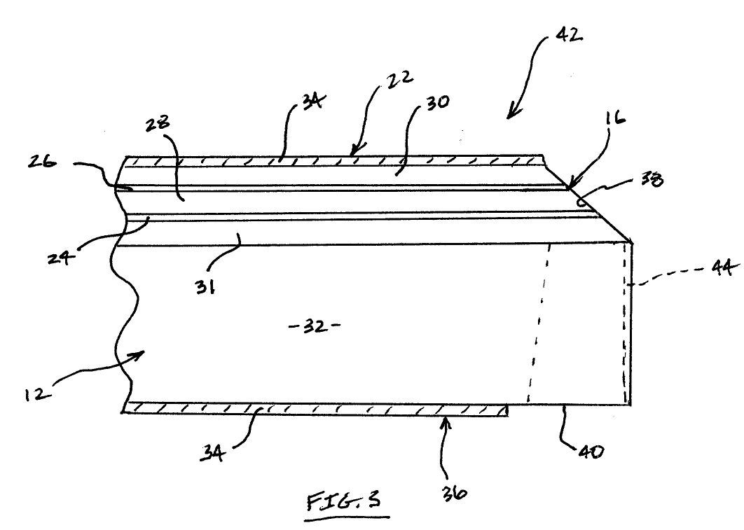

Accordingly, diode laser of this invention can be configured to be surface emitting diode lasers, wherein the laser beam is directed from the internally reflective wall surface through a few layers and out a surface, e.g., a top surface, of the diode laser (as illustrated in FIGS. 1 and 2), or can be configured to be substrate emitting diode lasers, wherein the laser beam is directed from the internally reflective wall surface through the substrate and out of a surface, e.g., a bottom surface, of the diode laser (as illustrated in FIG. 3).

Suitable materials useful as substrates for forming diode lasers of this invention can include those conventionally used to form semiconductor constructions. When used in forming substrate emitting diode lasers, in the event that the substrate is opaque or otherwise nontransparent to the laser light produced by the construction, a portion of substrate material interposed between the internally reflective wall surface and the emitting surface of the diode laser can be removed, e.g., by chemical process and/or other beam therethrough and outwardly from the diode laser surface.

It is to be understood that any reference made in this application to a “surface”, of the diode laser from which a laser beam is emitted, is understood to include the top surface or the bottom surface of the diode laser construction, depending on the particular diode laser configuration, i.e., whether it is a surface emitting laser or a substrate emitting laser.

FIG. 1 illustrates in schematic form an example semiconductor laser or diode laser 10 constructed and prepared according to the principles of this invention. The semiconductor laser 10 is constructed in the form of a semiconductive die 12 that typically includes an amplifying optical waveguide or a laser stripe 14 (which may also be referred to as a laser strip) extending a distance along the construction and oriented running generally parallel to a top surface of the construction. The laser stripe 14 is configured having a width, depth and length within the diode laser structure that can and will vary depending on such factors as the particular construction and/or materials of the different elements used to form the same, and on the particular end-use laser application. In an example embodiment, the laser stripe 14 is specially configured to both generate a laser beam 18 having a desired wavelength therein, and direct the laser beam 18 in a desired direction within the die 12. The laser stripe can be of any standard design, for example, a buried heterostructure stripe or a ridge waveguide stripe as well known in the art. The laser strip can be a single-mode laser stripe, such as a master oscillator power amplifier laser stripe.

While the device illustrated in FIG. 1 is a diode laser, it is to be understood that surface or substrate emitting constructions made according to the principles of this invention can be any type of diode laser and/or optical amplifier construction, and/or any type of nonamplified optical device construction such as an optical modulator, and/or any type of non-laser optoelectronic device such as detectors and modulators that use beam deflectors.

In the embodiment of FIG. 1, the laser stripe 14 is configured to direct the laser beam towards a region of the die 12 where a reflective element 16 of the diode laser structure is positioned. The location of the reflective element 16 relative to the die is understood to vary depending on the particular device construction and/or on its end-use application.

In the example embodiment illustrated in FIG. 1, the reflective element 16 is specially configured and/or oriented within the diode laser structure to cause the laser beam 18 to be internally reflected within the structure so that the reflected beam 18 emits from a top surface 22 of the die 12. As noted above, the reflective element can be configured and/or oriented other than that illustrated in FIG. 1, e.g., to facilitate reflecting the laser beam through the substrate material such that it emits from a bottom surface of the die. A feature of diode laser constructions prepared according to principles of this invention is that the reflective element 16 is provided in the form of an internally reflective wall surface that itself is made during the process of forming the diode laser structure.

FIG. 2 is a cross-sectional view of an example embodiment surface emitting diode laser 10, constructed in accordance with the principles of this invention, illustrating the different elements and/or layers used for making the diode laser construction. In this example, the die 12 includes a gain or active layer 24 having a desired width and thickness, and that extends a desired length within the structure. The gain layer runs parallel with an axis of the laser stripe (shown in FIG. 1).

The gain layer 24 can be formed from materials selected from the group including but not limited to Indium (In), Gallium (Ga), Arsenic (As), Phosphorus (P), Aluminum (Al), and combinations thereof such as InGaAs, InGaAsP, InGaAlAs, and the like. The gain layer can comprise a single layer or multiple layers of materials. In an example embodiment, the gain layer 24 can be formed from multiple “quantum-wall” sublayers separated by “quantum barriers” with a typical thickness on the order of about 10 nanometers.

In an example embodiment, the gain layer 24 is interposed between a P-type cladding layer 30 and an N-type cladding layer 31 to provide the optical gain required for oscillation, wherein the N-type cladding layer 31 is deposed on a substrate 32. The P-type cladding layer 30 can be formed from those material used to form P-type cladding layers in conventional diode laser constructions. Example materials useful for forming the P-type cladding layer include but are not limited to AlGaAs doped with Zinc (Zn) and might typically have a thickness of about 2 micrometers.

The N-type cladding layer 31 can be formed from those material used to form N-type cladding layers in conventional diode laser constructions, and for example can be of similar construction as the P-type cladding layer but doped with Silicon instead of Zn. In this example embodiment the substrate 32 is an N-type substrate formed from the same types of material used to form N-type substrates in conventional diode laser constructions, and for example can be formed from the same type of material used to form the N-type cladding layer 31.

A diffraction grating feedback layer 26 is interposed between and runs parallel to the P-type cladding layer 30 and a spacer layer 28. The spacer layer 28 is typically of similar composition to that of the P-type cladding layer 30, and in an example embodiment is approximately 100 nanometers thick. The spacer layer is useful for providing a distance from the gain layer 24 to help protect the gain layer from any unwanted effects that may occur during the process of forming the diffraction grating feedback layer 26. The diffraction grating feedback layer 26 can be positioned above or below the gain layer 24 depending on the particular diode laser construction, and in this example embodiment is positioned above the gain layer 24.

In an example embodiment, the diffraction grating feedback layer 26 is formed from a semiconductor alloy having a refractive index that is different from that of the P-type cladding layer 30. In this example, the diffraction grating feedback layer 26 is corrugated with a period satisfying the Bragg condition for the desired frequency of oscillation.

In an example embodiment, the diffraction grating feedback layer can be formed from AlGaAs having a higher Ga to Al ratio than the cladding layers, and typically has a thickness of about 30 nanometers. The diffraction grating feedback layer can have a corrugation period typically from between about 100 to 400 nanometers, wherein the corrugation period can be constant or variable with one or more phase shifts, e.g., spectral characteristics.

The diffraction grating feedback layer 26 may extend along an entire or only a partial length of the diode laser structure depending on the particular diode laser construction and end-use application. If the diffraction grating feedback layer 26 extends along a partial length of the diode laser structure, its length and placement position relative to the other layers above and below the diffraction grating feedback layer 26 is understood to vary depending on the diode laser construction and end-use application, e.g., it can be positioned towards a rear part or a front part of the diode laser construction. Additionally, the corrugated portion of the diffraction layer may extend over the entire length or along only a partial length of the diffraction grating feedback layer depending on the particular diode laser structure and/or its end-use application.

In an example embodiment, the diffraction grating feedback layer 26 extends a along an entire length of the diode laser structure, and includes a corrugated section that extends partially along its length and that is positioned towards a back or rear portion of the diode laser structure away from the internally reflective surface or element 16.

While the diode laser of this example embodiment has been described as having a diffraction grating feedback layer in the form of a separate material layer within the diode laser construction, it is to be understood that diode lasers of this invention can include a diffraction grating that not provided in the form of a separate layer. In such alternative embodiment, the function of the diffraction grating can be provided from the active or gain layer, i.e., be a gain grating, wherein the active or gain layer itself is corrugated by appropriate forming technique to produce the desired diffraction grating function.

Further, while the example embodiment illustrated in FIG. 2 illustrates use of a diffraction grating feedback layer 26, diode lasers of this invention can be made without a grating layer altogether by utilizing the Freshel refraction from the rear edge portion of the diode laser and a reflection from either the emitting surface of the diode or from an interface refraction within the diode to form a Fabry-Perot resonator.

Referring still to FIG. 2, the diode laser 10 includes electrical contacts 34 that may be located at both the top surface 22 and a bottom surface 36 of the die 12. The electrical contacts 34 are connected to a source of electrical power (not shown) that induces a migration of holes and electrons from the layers 28, 30 and 31 to the active layer 24. The holes and electrons recombine and emit photons.

The reflective element 16 disposed within the diode laser structure includes an internally reflective surface 38 that is specifically oriented and positioned to reflect the laser beam produced within the diode laser and pass it upwardly through the layers positioned between the active layer 24 and the top surface 22, e.g., the spacer layer 28 and the P-type cladding layer 30 in a desired direction outwardly from the top surface. In an example embodiment, the laser beam exits the top surface 22 via an exit facet 40 or the like, which can simply be a surface of the P-type cladding layer 30 that is transparent or that has been rendered transparent by appropriate treatment, and that does not include the electrical contacts 34.

If desired, the exit facet 40 can be configured having an anti-reflection coating or the like to ensure that no amount of the laser beam directed to it from the internally reflective surface 38 is reflected back into the diode laser. Alternatively, the exit facet 40 can be configured having a reflective coating or the like to provide some desired degree of laser beam reflection back into the diode laser, e.g., to provide a desired degree of laser feedback at the front end of the diode laser.

In an example embodiment, the internally reflective wall surface 38 is formed at an approximate 45 degree angle relative to the direction of the laser beam produced within the diode laser. In a diode laser construction where the direction of the laser beam produced within the diode laser is parallel to the top surface 22, the internally reflective wall surface 38 orientation of approximately 45 degrees operates to reflect the laser beam produced within the diode laser through the surface layer at an approximate 90 degree angle to cause the laser beam to be projected within the diode laser perpendicular to the top surface 22 for emission therefrom.

While an example internally reflective wall surface 38 orientation of 45 degrees has been disclosed to provide a laser beam emission from the surface 22 that is perpendicular thereto, it is to be understood that diode lasers of this invention can be constructed having an internally reflective wall surface 38 that is oriented differently to suited for a particular end-use application.

The semiconductive die 12 useful for forming diode lasers can be grown on III-V types of semiconducting substrates, such as on indium-phosphide, gallium-arsenide, or the like. However, it is to be understood that diode lasers of this invention can be formed on crystalline planes other than the (111)B plane if desired.

While a surface emitting diode laser has been described above and illustrated in FIGS. 1 and 2 comprising an N-type substrate and differently arranged N- and P-type cladding layers, it is to be understood that surface emitting diode lasers prepared in accordance with the principles of this invention can comprise a P-type substrate that the N- and P-type cladding layers substituted as necessary to produce the desired semiconductive effect.

While the example surface emitting diode laser illustrated in FIG. 2 is shown having a number of different layers, the number and type of layers illustrated has been limited for purposes of reference and clarity. It is, therefore, to be understood that surface emitting diode lasers of this invention having material layers in addition to those illustrated in FIG. 2 are within the scope of this invention. Additionally, it is to be understood that the relative dimensions and/or scale of the different material layers shown in FIG. 2 are provided for purposes of reference. Accordingly, surface emitting diode lasers having material layers that are dimensioned and/or scaled differently from that illustrated in FIG. 2 are understood to be within the scope of this invention.

FIG. 3 illustrates a example embodiment substrate emitting diode laser 42, constructed according to principles of this invention in the form of a die 12, comprising an N-type substrate 32 of desired thickness, an N-type cladding layer 31 disposed onto a surface of the substrate, a gain or active layer 24 disposed onto the N-type cladding layer 31, a spacer layer 28 disposed onto the gain layer, a diffraction grating feedback layer 26 disposed on the spacer layer, and a P-type cladding layer 30 disposed onto the diffraction grating feedback layer. Electrical contacts 34 are positioned along the top and bottom surfaces 22 and 36 of the construction.

The materials used to form the substrate and different semiconductive layers of this substrate emitting diode laser construction can be the same as those described above for the same respective substrate and layers of the surface emitting diode laser construction. Additionally, it is to be understood that the type of materials can be interchanged from N-type materials to P-type material to produce the desired semiconductive effect.

Like the surface emitting diode laser embodiment, the substrate emitting diode laser 42 also includes a reflective element 16 in the form of an internally reflective wall surface 38 that is formed in situ during the epitaxial deposition process used for forming the different layers on the substrate 32. The internally reflective wall surface 38 is oriented at a desired angle relative to the path of the laser beam radiation produced with the diode laser structure to cause the laser beam to be reflected downwardly through the underlying layers deposited on the substrate, and then through the substrate 32. The laser beam exits the diode laser construction through a exit facet 40 of the substrate bottom surface 36 that is not covered by the electrical contacts 34.

As briefly noted above, if the substrate 32 is opaque or is otherwise not optically transparent, an exit via 44 can be formed within the substrate to facilitate passage of the laser beam through the substrate 32 and outwardly away from the bottom surface. The exit via 44 can be formed by conventional techniques used to form vias in substrates used for semiconductor fabrication, e.g., by etching process or the like.

The angle of orientation for the internally reflective wall surface 38 can and will vary depending on the particular angle of orientation desired for laser beam exiting the bottom surface. In an example embodiment, the internally reflective wall surface 38 in this substrate emitting diode laser embodiment is oriented at an approximate 45 degree angle relative to the direction of the laser beam radiation being produced within the diode laser structure, and at an approximate 45 degree angle relative to the bottom surface 36 of the substrate, thereby producing a laser emission that is perpendicular to or oriented at a 90 degree angle relative to the bottom surface 36.

As noted above for the surface emitting diode laser embodiment, the substrate emitting diode laser 42 can be configured having one or more reflective layers that are the substrate and the other semiconductive layers to provide a desired degree of laser feedback. Alternatively or in addition to using such reflective layers at the substrate interface surface, the diode laser can be constructed having one or more reflective layers disposed onto the exit facet 40 on the bottom surface of the substrate. Such reflective layers can be used in conjunction with or to replace the diffraction grating feedback layer 26.

While the example substrate emitting diode laser illustrated in FIG. 3 is shown having a number of different layers, the number and type of layers illustrated has been limited for purposes of reference and clarity. It is, therefore, to be understood that substrate emitting diode lasers of this invention having material layers in addition to those illustrated in FIG. 3 are within the scope of this invention. Additionally, it is to be understood that the relative dimensions and/or scale of the different material layers shown in FIG. 3 are provided for purposes of reference. Accordingly, substrate emitting diode lasers having material layers that are dimensioned and/or scaled differently from that illustrated in FIG. 3 are understood to be within the scope of this invention.

A feature of diode lasers as constructed and formed according to principles of this invention is that the internally reflective surface 38 is formed during the epitaxial deposition process that is used to form the different layers of the of the diode laser itself. Thus, diode lasers of this invention have an internally reflective surface that is formed in situ during formation of the diode laser structure itself, rather than being formed after the diode laser is constructed by subsequent process of cutting, cleaving, or etching. The advantages of such in situ process of making the internally reflective surface will be described below.

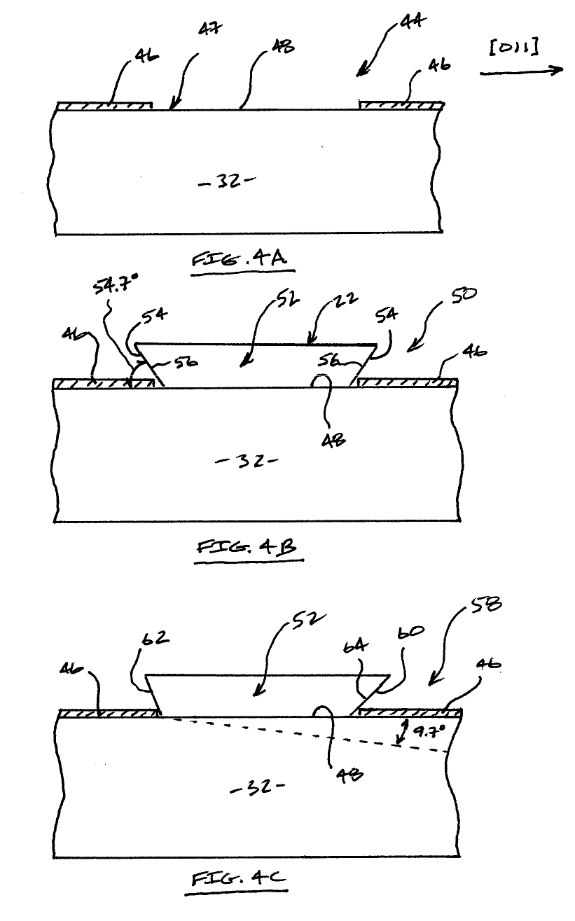

FIGS. 4A to 4C illustrate a surface emitting diode laser of this invention at different stages of formation to help show how the internally reflective wall surface is made during the diode laser fabrication process. FIG. 4A illustrates an early stage of the diode laser fabrication process 44 where one starts with a desired substrate material 32 selected from the same types of substrate materials described above, such as a III-V compound substrate. In this particular embodiment, the substrate is a (100) oriented III-V compound substrate, and the axis of the laser stripe is oriented in the [01 1̅] direction (moving from left to right along FIGS. 4A to 4C).

A selective growth mask 46 is formed at desired locations on the top surface 47 of the substrate 32. In an example embodiment, the mask 46 is provided in two or more locations to provide an unmasked substrate surface section 48 therebetween, thereby forming a patterned substrate. The mask or masks can be formed by conventional techniques known in the art for forming semiconductor constructions, e.g., by photolithographic method or the like. In an example embodiment, the growth masks 46 are formed from a film of silicon dioxide approximately 200 nanometers thick deposited by chemical vapor deposition. The mask or masks operate to direct subsequent epitaxial growth on the substrate to the unmasked surface section 48.

FIG. 4B illustrates the surface emitting diode laser during a subsequent stage 50 of fabrication after the masks 46 have been formed, and after one or more layers 52 of the materials useful for forming the diode laser have been deposited onto the substrate surface section 48 by epitaxial deposition or growth. For purposes of simplicity and reference, the individual layers in the body 52 of layers have not illustrated, but can be the same as those described above and illustrated in FIG. 2. The corrugated section of the diffraction grating feedback layer can be formed by conventional techniques, such as by masking and etching processes or the like.

The body of layers 52 disposed on the substrate and forming the diode laser in this step 50 includes two wall surfaces 54 at each end of the body. In this particular embodiment, the substrate 32 that was used was a conventionally (100) oriented substrate, and as a result the wall surfaces of the body formed during epitaxial growth each have an angle of incline relative to the substrate surface of approximately 54.7 degrees. Thus, the internally reflective wall surface 56 of this construction would operate to reflect a laser beam produced within the diode laser construction upwardly through the upper layers of the body 52. The reflected laser beam would have an angle of inclination that was other than 90 degrees relative to the top surface, i.e., that was not perpendicular to the top surface.

A surface emitting laser having a laser beam that is emitted perpendicular to the top surface can be achieved by forming a diode laser having an internally reflective wall surface oriented at an angle of approximately 45 degrees. As illustrated in FIG. 4B, this cannot be achieved by using a conventional (100) oriented substrate.

FIG. 4C illustrates the surface emitting diode laser during a subsequent stage 58 of fabrication after the masks 46 have been formed, and after one or more layers 52 of the materials useful for forming the diode laser have been deposited onto the substrate surface section 48 by epitaxial deposition or growth. Again, the individual layers in the body 52 of layers have not illustrated for purpose of simplicity and reference.

Unlike the substrate used in FIG. 4B, the substrate used FIG. 4C in one that is vicinally oriented in that is it inclined at an angle of approximately 9.7 degrees from the (100) orientation towards the (111)A plane. It has been discovered that by starting with such a vicinally-oriented substrate 32, the wall surfaces 60 and 62 of the body 52 formed during epitaxial growth have an angle of incline relative to the substrate surface of approximately 45 degrees and 64.4 degrees, respectively. Thus, the internally reflective wall surface 64 of this construction would operate to reflect a laser beam produced within the diode laser construction upwardly through the upper layers of the body 52 and outwardly through the top surface 22 of the body 52 at an angle of approximately 90 degrees, or perpendicular, relative to the top surface.

Once the desired material layers are formed, the remaining features of the diode laser, such as the electrical contacts, any exit facet coatings and the like can then be provided. A feature of this fabrication technique is that the internally reflective wall surface is formed during the process of forming the desired layers of materials by epitaxial deposition or growth, and the wall surface formed thereby has a high level of smoothness, e.g., has a roughness of a fraction of an optical wavelength.

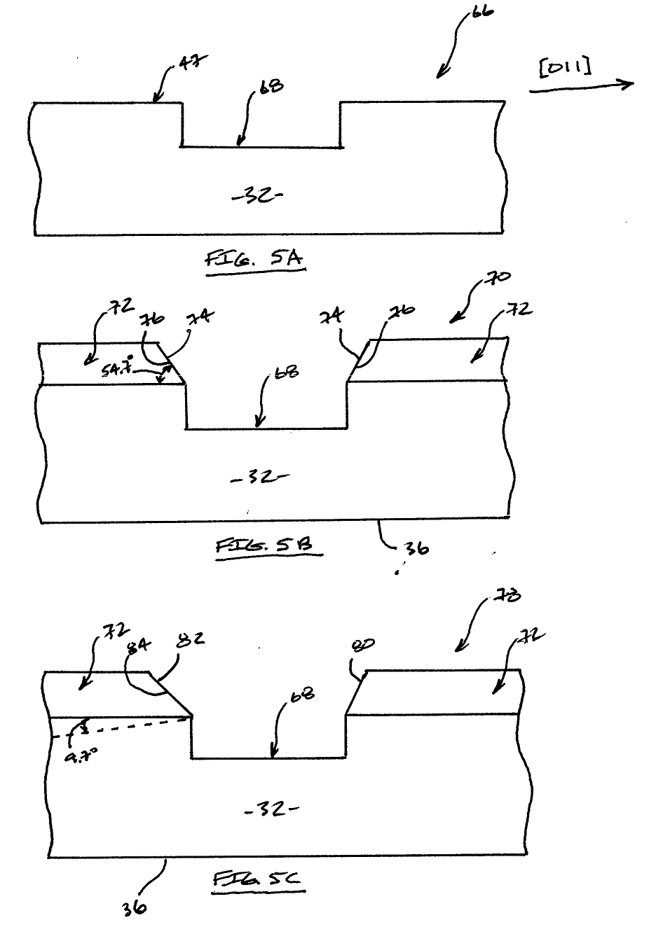

Instead of using a patterned selective growth mask such as 46 to define the location of the internally reflective wall, the same structure may alternatively be defined by epitaxial growth over a substrate with a stepped surface. FIGS. 5A to 5C illustrate a substrate emitting diode laser of this invention at different stages of formation to help process. FIG. 5A illustrates an early stage of the diode laser fabrication process 66, starting with a desired substrate material 32 selected from the same types of substrate materials described above for the surface emitting diode laser. In this particular embodiment, the substrate 32 is a (100) oriented III-V compound substrate, and the axis of the laser stripe is oriented in the [01 1̅] direction (moving from left to right along FIGS. 5A to 5C).

One or more sections of the substrate surface 47 are removed by conventional technique used in semiconductor fabrication processing, such as by etching or the like, forming a stepped surface characterized by one or more recessed grooves or channels 68. The formation of such a stepped surface is used to facilitate crystalline growth by epitaxial deposition. In an example embodiment, the groove or channel can be about 2 to 20 micrometers depth and about 5 to 200 micrometers wide. However, it is to be understood that the exact dimensions of the groove can and will vary depending on the particular diode laser construction and its end-use application.

FIG. 5B illustrates the substrate emitting diode laser during a subsequent stage 70 of fabrication after the one or more grooves 68 has been formed, and after one or more layers 72 of the materials useful for forming the diode laser have been deposited onto the substrate surface 47 adjacent the groove 68 by epitaxial deposition or growth. For purposes of simplicity and reference, the individual layers in the body 72 of layers have not illustrated, but can be the same as those described above and illustrated in FIG. 3. The corrugated section of the diffraction grating feedback layer can be formed by conventional techniques, such as by masking and etching processes or the like.

As illustrated, one or more bodies 72 of layers are formed on the substrate. In an example embodiment, two bodies 72 are formed and are separated from one another by the groove 68. The bodies 72 of layers disposed on the substrate and forming the diode laser in this step 70 include two wall surfaces 74 at each end of the body. In this particular embodiment, the substrate 32 that was used was a conventionally (100) oriented substrate, and as a result the wall surfaces 74 of the body formed during epitaxial growth each have an angle of incline relative to the substrate surface of approximately 54.7 degrees. Thus, the internally reflective wall surfaces 76 of this construction would operate to reflect a laser beam produced within the diode laser construction downwardly through the lower layers of the bodies 72. The reflected laser beam would have an angle of inclination other than 90 degrees relative to the bottom surface, i.e., not perpendicular to the bottom surface.

A substrate emitting diode laser having a laser beam that is emitted perpendicular to the bottom surface can be achieved by forming a diode laser having an internally reflective wall surface oriented at an angle of approximately 45 degrees. As illustrated in FIG. 5B, this cannot be achieved by using a conventional (100) oriented substrate.

FIG. 5C illustrates the substrate emitting diode laser during a subsequent stage 78 of fabrication after the one or more grooves 68 have been formed, and after one or more layers 52 of the materials useful for forming the diode laser have been deposited onto the substrate surface by epitaxial deposition or growth. Again, the individual layers in the body 52 of layers have not been illustrated for purpose of simplicity and reference.

Unlike the substrate used in FIG. 5B, the substrate used FIG. 5C is one that is vicinally oriented in that it is inclined at an angle of approximately 9.7 degrees from the (100) orientation towards the (111)B plane. It has been discovered that by starting with such a vicinally-oriented substrate 32, the wall surfaces 80 and 82 of each respective body 72 formed during epitaxial growth have an angle of incline relative to the substrate surface of approximately 45 degrees and 64.4 degrees, respectively. Thus, the internally reflective wall surface 84 of this construction would operate to reflect a laser beam produced within the diode laser construction downwardly through the lower layers of the body 72 and outwardly through the substrate bottom surface 36 at an angle of approximately 90 degrees, or perpendicular, relative to the bottom surface.

Once the desired material layers are formed, the remaining features of the diode laser, such as the electrical contacts, any exit facet coatings and the like can then be provided. As with the surface emitting diode laser embodiment, a feature of this fabrication technique used to form the substrate emitting diode laser is that the internally reflective wall surface is formed during the process of forming the desired layers of materials by epitaxial deposition or growth, and the wall surface formed thereby has a the order of about 1/10^{th} of a wavelength.

While the use of a particular type of substrate having a specific crystallographic structure and/or orientation has been disclosed above, it is to be understood that diode lasers of this invention can be constructed using different substrates having different crystallographic structures that may or may not require pretreatment or preparation to ensure that the further layers that are grown or disposed thereon result in the formation of an internally reflective wall surface having a desired angle or orientation to reflect the laser beam in a manner producing a laser emission from a top or bottom surface of the diode laser having a particular angle or inclination relative to such surface. Accordingly, it is to be understood that the invention as described herein applies to the use of all such other substrate structures, and that the use of such all other substrate structures is intended to be within the scope of this invention.

Again, as noted above, a feature of diode laser constructions formed according to principles of this invention is that the layers of material that are subsequently formed or epitaxially grown on the substrate are intentionally provided in a manner that produces an internally reflective wall surface having a desired angle of inclination that is provided to cause the laser beam produced therein to be reflected in a manner facilitating its emission from a top or bottom surface of the diode laser.

Diode lasers constructed in the manner described herein can be configured having one or more monolithically integrated optical elements if so desired, such as lenses, prisms, diffraction gratings, or the like.

While certain methods of making diode lasers has been described above in the context of a single diode laser, it is to be understood that a number of diode lasers can be made according to the above-described process in parallel on a single wafer, which can then be cut into the individual diode lasers, and which can be used individually. Alternatively, the number of diode lasers that are formed at the same time on a single wafer can be used together to form a diode laser array, e.g., one-dimensional and two-dimensional laser arrays.

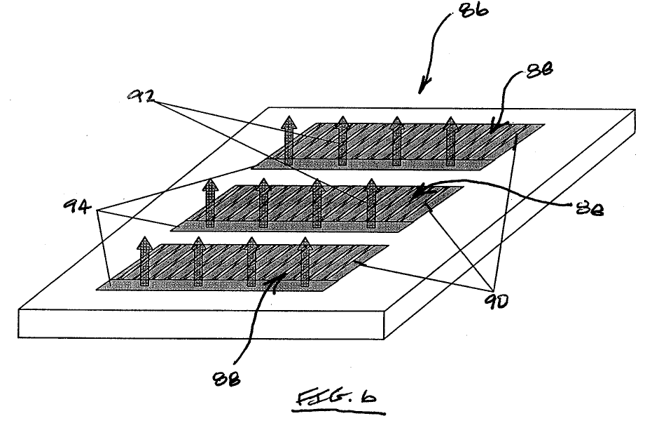

FIG. 6 illustrates an example embodiment of a two-dimensional array 86 of surface emitting diode lasers prepared according to principles of this invention. In this particular example, the array 86 comprises three diode laser structures 88 that each comprise a plurality of laser stripes 90 as described above and illustrated in FIG. 1. The diode laser structures 88, and the laser stripes 90 disposed therein, all comprise internally reflective wall surfaces that are configured, oriented, and formed in the manner noted above to produce a plurality of laser beam emissions 92 from the top surfaces 94 of the diode laser structures. In an example embodiment, the internally reflective wall surfaces are all oriented at the same angle to produce laser beam emissions exiting the top surface of the diode laser structures at the same angle of inclination relative to the top surface. In a preferred embodiment, the internally reflective wall surface is oriented at an approximate 45 degree angle relative to the laser beam produced within each respective laser stripe to provide laser beam emissions from the array that are each perpendicular to the diode laser structure top surface.

While a particular two-dimensional array of diode lasers prepared according to principles of this invention have been described above and illustrated in FIG. 6, it is to be understood that many other configurations of two-dimensional arrays using diode lasers of this invention are possible and are intended be within the scope of the invention. Additionally, while not illustrated, it is to be understood that diode lasers of this invention can be used to form one-dimensional arrays for use in certain end-use applications. In an example embodiment, such a one-dimensional laser array would include one of the diode laser structures 88 illustrated in FIG. 6.

While certain exemplary embodiments have been described and shown in the accompanying drawings, it is to be understood that such embodiments are merely illustrative of and not restrictive on the broad invention, and that this invention not be limited to the specific constructions and arrangements shown and described, since various other modifications may occur to those ordinarily skilled in the art. In particular, an essentially equivalent laser could be made if the conductivity types of P-doped and N-doped layers are reversed, or if the positions of the active layer and distributed feedback layers are reversed.

Further, while the method described above has been presented in the context of producing one or more diode lasers, it is to be understood that this method can be used to produce any type of photon generating, photon emitting, and or photon transmitting device wherein it is desired that the photons being generated and/or passed therein be internally reflected for facilitating photon or laser beam emission in a direction outwardly from a top or bottom surface of the device.

Still further, the process of using epitaxial growth to form the laser structure and the internally reflective wall surface may be performed other than as described. For example, epitaxial growth to form the laser structure and the internally reflective wall surface can be performed in a single growth step, or can alternatively be performed in several steps with intermediate stages of processing. For example, corrugation of the diffraction grating feedback layer can be performed in between growth steps.

Other modifications and variations of constructions and methods as practiced according to the principles of this invention will be apparent to those skilled in the art. It is, therefore, to be understood that within the scope of the appended claims, this invention may be practiced otherwise than as specifically described.

What is claimed is:

1. A diode laser construction comprising:
a substrate;
a number of material layers disposed onto the substrate, wherein the material layers include a P-type material layer, and an N-type material layer, wherein the materials layers are formed by epitaxial deposition, and wherein the material layers include an internally reflective wall surface, wherein the internally reflective wall surface is produced during the process of forming the material layers by epitaxial deposition, the internally reflective wall surface being oriented at an angle relative to the direction of a laser beam produced by the construction to reflect the laser beam toward one of a top or bottom surface of the diode laser construction.

2. The diode laser as recited in claim 1 wherein the material layers further comprise:
a gain layer that is interposed between the P-type layer and the N-type layer; and
a diffraction grating feedback layer that is positioned parallel to the gain layer, wherein the diffraction grating feedback layer includes a corrugated section to provide a desired laser beam frequency of oscillation.

3. The diode laser as recited in claim 2 wherein the corrugated section extends along a partial length of the diffraction grating feedback layer that is positioned a distance away from the internally reflective wall surface.

4. The diode laser as recited in claim 1 wherein the material layers further comprise:
a gain layer that is interposed between the P-type layer and the N-type layer; and
a diffraction grating feedback layer, wherein the diffraction grating feedback layer that is formed from a corrugated section of the gain layer to provide a desired laser beam frequency of oscillation.

5. The diode laser as recited in claim 1 wherein the internally reflective wall surface is oriented to reflect the laser beam produced within the diode laser construction through one or more material layers and out of a top surface of the diode laser construction formed from one of the material layers.

6. The diode laser as recited in claim 1 wherein the internally reflective wall surface has an inherent roughness of a fraction of a wavelength.

7. The diode laser as recited in claim 1 wherein the internally reflective wall surface has an inherent roughness that is less than about 1/10 of a wavelength.

8. The diode laser as recited in claim 1 wherein the internally reflective wall surface is oriented at an angle of approximately 45 degrees relative to one of the top or bottom surface of the construction.

9. The diode laser as recited in claim 1 wherein the internally reflective wall surface is oriented to reflect the laser beam produced within the diode laser construction through the substrate and out of a bottom surface of the construction.

10. The diode laser as recited in claim 1 wherein the substrate is a III-V compound and is inclined at an angle of approximately 9.7 degrees from a (100) orientation.

11. A monolithic array of diode lasers comprising a plurality of the diode laser constructions recited in claim 1, wherein the internally reflective wall surface of each of the diode laser constructions are oriented at the same angle relative to such diode laser to produce a plurality of laser beam emissions that have a common angle of inclination relative to one of the top or bottom surface of the diode laser constructions.

12. The monolithic array as recited in claim 11 wherein the array of diode lasers is a one-dimensional array.

13. The monolithic array as recited in claim 11 wherein the array of diode lasers is a two-dimensional array.

14. The diode laser as recited in claim 1 further comprising one or more optical element selected from the group consisting of lenses, prisms, and diffraction gratings.

15. The diode laser as recited in claim 1 wherein the material layers include an end surface opposite the internally reflective wall surface, and wherein the end surface reflects the laser beam towards the internally reflective wall surface.

16. The diode laser as recited in claim 1 further comprising a reflective surface positioned downstream from the internally reflective wall.

17. The diode laser as recited in claim 16 wherein the reflective surface is positioned adjacent one or more of the material layers.

18. The diode laser as recited in claim 1 comprising a laser stripe formed from the material layers, the laser stripe oriented in a parallel direction parallel relative to one of the top or bottom surfaces of the diode laser construction.

19. The diode laser as recited in claim 18 wherein the laser stripe is a single-mode laser stripe.

20. A surface emitting diode laser construction comprising:
a substrate formed from a III-V compound;
a number of material layers disposed onto the substrate, the material layers being formed by epitaxial deposition and including at least a P-type material layer and an N-type material layer, the number of material layers including an internally reflective wall surface that is formed during the epitaxial deposition process used for making the material layers, the internally reflective wall surface being oriented to reflect a laser beam produced within the material layers internally within one or more of the material layers so that the laser beam is emitted outwardly from the construction at a top surface of the material layers.

21. The surface emitting diode laser construction as recited in claim 20 wherein the internally reflected wall surface has an inherent roughness of less than about 1/10 of a wavelength.

22. The surface emitting diode laser construction as recited in claim 20 wherein the material layers further include a gain layer that is interposed between the P-type material layer and the N-type material layer.

23. The surface emitting diode laser construction as recited in claim 22 wherein the material layers further include a diffraction grating feedback layer that is positioned parallel to the gain layer and that includes a corrugated section having a period that produces a desired laser beam frequency of oscillation.

24. The surface emitting diode laser construction as recited in claim 23 wherein the corrugated section extends along a partial length of the diffraction grating feedback layer that is positioned a distance away from the internally reflective wall surface.

25. The surface emitting diode laser construction as recited in claim 23 wherein the material layers further comprise a spacer layer interposed between the gain and diffraction grating feedback layers, wherein the spacer layer is formed from one of a P-type material or an N-type material.

26. The surface emitting diode laser construction as recited in claim 23 wherein the diffraction grating feedback layer corrugated section is formed from the gain layer.

27. The surface emitting diode laser as recited in claim 23 further comprising one or more optical element selected from the group consisting of lenses, prisms, and diffraction gratings.

28. The surface emitting diode laser as recited in claim 23 wherein the material layers include an end surface opposite the internally reflective wall surface, and wherein the end surface reflects the laser beam towards the internally reflective wall surface.

29. The surface emitting diode laser as recited in claim 23 further comprising a reflective surface positioned downstream from the internally reflective wall.

30. The surface emitting diode laser as recited in claim 29 wherein the reflective surface is positioned adjacent one or more of the material layers.

31. The surface emitting diode laser construction as recited in claim 20 wherein the substrate is inclined at an angle of approximately 9.7 degrees from a (100) orientation.

32. The surface emitting diode laser construction as recited in claim 31 wherein the internally reflective wall surface is oriented at an angle of approximately 45 degrees relative to the top surface of the material layers.

33. An array of diode lasers comprising a number of the surface emitting diode laser constructions recited in claim 15, wherein the internally reflective wall surface of each diode laser construction is oriented at the same angle to produce a number of laser beam emissions that have a common angle of inclination relative to the top surface of the material layers.

34. The array of diode lasers as recited in claim 33 wherein the array is a one-dimensional array.

35. The array of diode lasers as recited in claim 33 wherein the array is a two-dimensional array.

36. A substrate emitting diode laser construction comprising:
a substrate formed from a III-V compound;
a number of material layers disposed onto the substrate, the material layers being formed by epitaxial deposition and including at least a P-type material layer and an N-type material layer, the number of material layers including an internally reflective wall surface that is formed during the epitaxial deposition process used for making the material layers, the internally reflective wall surface being oriented to reflect a laser beam produced within the material layers internally within one or more of the material layers and the substrate so that the laser beam is emitted outwardly from the construction at a bottom surface of the substrate.

37. The substrate emitting diode laser construction as recited in claim 36 wherein the internally reflected wall surface has an inherent roughness of a fraction of a wavelength.

38. The substrate emitting diode laser construction as recited in claim 37 wherein the internally reflected wall surface has an inherent roughness of less than about 1/10 of a wavelength.

39. The substrate emitting diode laser construction as recited in claim 37 wherein the material layers further include a gain layer that is interposed between the P-type material layer and the N-type material layer.

40. The substrate emitting diode laser construction as recited in claim 39 wherein the material layers further include a diffraction grating feedback layer adjacent the gain layer and that includes a corrugated section having a period that produces a desired laser beam frequency of oscillation.

41. The substrate emitting diode laser construction as recited in claim 40 wherein the diffraction grating feedback layer corrugated section is formed from the gain layer.

42. The substrate emitting diode laser construction as recited in claim 40 wherein the material layers further comprise a spacer layer interposed between the gain and diffraction grating feedback layers, wherein the spacer layer is formed from one of a P-type material or an N-type material.

43. The substrate emitting diode laser construction as recited in claim 40 wherein the corrugated section extends along a partial length of the diffraction grating feedback layer that is positioned a distance away from the internally reflective wall surface.

44. The substrate emitting diode laser construction as recited in claim 36 wherein the substrate is inclined at an angle of approximately 9.7 degrees from a (100) orientation.

45. The substrate emitting diode laser construction as recited in claim 44 wherein the internally reflective wall surface is oriented at an angle of approximately 45 degrees relative to the bottom surface of the substrate.

46. The substrate emitting diode laser as recited in claim 36 further comprising one or more optical element selected from the group consisting of lenses, prisms, and diffraction gratings.

47. The substrate emitting diode laser as recited in claim 36 wherein the material layers include an end surface opposite the internally reflective wall surface, and wherein the end surface reflects the laser beam towards the internally reflective wall surface.

48. The substrate emitting diode laser as recited in claim 36 further comprising a reflective surface positioned downstream from the internally reflective wall.

49. The substrate emitting diode laser as recited in claim 48 wherein the reflective surface is positioned adjacent one or more of the material layers.

50. An array of diode lasers comprising a number of the substrate emitting diode laser constructions recited in claim 36, wherein the internally reflective wall surface of each diode laser construction is oriented at the same angle to produce a number of laser beam emissions that have a common angle of inclination relative to the bottom surface of the material layers.

51. The array of diode lasers as recited in claim 50 wherein the array is a one-dimensional array.

52. The array of diode lasers as recited in claim 50 wherein the array is a two-dimensional array.

53. An optical device construction comprising:
a substrate;
a number of material layers disposed onto the substrate, wherein the material layers are formed by epitaxial deposition, and wherein the material layers include an internally reflective wall surface, wherein the internally reflective wall surface is produced during the process of forming the material layers by epitaxial deposition, the internally reflective wall surface being oriented at an angle relative to the direction of a beam of light directed at least partially through the construction to reflect beam toward one of a top or bottom surface optical device construction.

54. A method for making a diode laser comprising the steps of:
forming a number of layers of material onto a substrate, the layers of material including an N-type material layer and a P-type material layer; and
forming an internally reflective wall surface in the number of layers of material, wherein the internally reflective wall surface is positioned along a common edge of the number of layers, wherein the internally reflective wall surface is formed during the step of forming the number of material layers, and wherein the internally reflective wall surface is oriented during the step of forming having an angle of inclination that reflects a laser beam produced within the diode laser through one or more of the number of material layers to exit from a top or bottom surface of the diode laser.

55. The method as recited in claim 54 wherein during the step of forming the number of layers, a gain layer is formed and a diffraction grating feedback layer is formed, wherein the diffraction grating feedback layer includes a corrugated section.

56. The method as recited in claim 55 where during the step of forming the number of layers, a spacer layer is formed between the gain layer and the diffraction grating feedback layer.

57. The method as recited in claim 54 wherein the internally reflective wall surface is oriented to reflect the laser beam produced within the diode laser so that it exits out of the diode laser from a top surface of the number of layers.

58. The method as recited in claim 54 wherein the internally reflective wall surface is oriented to reflect the laser beam produced within the diode laser so that it exits out of the diode laser from a bottom surface of the substrate.

59. The method as recited in claim 54 wherein the substrate is a III-V compound that is inclined at an angle of approximately 9.7 degrees from a (100) orientation.

60. The method as recited in claim 59 wherein the internally reflective wall surface is oriented at an angle of approximately 45 degrees relative to one of the top or bottom surface of the diode laser.

61. The method as recited in claim 60 wherein the laser beam exits the diode laser at an approximate angle of inclination of 90 degree relative to one of the top or bottom of the diode laser.

62. A method for making a surface emitting diode laser comprising the steps of:
forming a number of material layers onto a III-V compound substrate, the material layers being formed by epitaxial deposition and including at least a P-type material layer and an N-type material layer; and
forming a wall surface along a common edge of the number of material layers during the step of forming the number of material layers, wherein the wall surface is an internally reflective surface that is oriented during the step of forming to reflect a laser beam produced within the number of material layers through one or more of the layers and out of a top surface of the number of material layers.

63. The method as recited in claim 62 wherein during the step of forming the wall surface, the internally reflective wall surface of the diode laser is oriented so that the laser beam produced within the diode laser exits the laser at a 90 degree angle relative to the top surface.

64. The method as recited in claim 62 wherein during the steps of forming the number of material layers, forming a gain layer that is interposed between the P-type material layer and the N-type material layer.

65. The method as recited in claim 62 wherein during the steps of forming the number of material layers, forming a diffraction grating feedback layer adjacent the gain layer.

66. The method as recited in claim 62 wherein the substrate is vicinally oriented an angle of approximately 9.7 degrees from a (100) orientation.

67. The method as recited in claim 62 wherein prior to the step of forming the number of material layers, patterning a surface of the substrate to produce a surface section along which the number of material layers will be formed.

68. A method for making a substrate emitting diode laser comprising the steps of:
forming a number of material layers onto a III-V compound substrate, the material layers being formed by epitaxial deposition and including at least a P-type material layer and an N-type material layer; and
forming a wall surface along a common edge of the number of material layers during the step of forming the number of material layers, wherein the wall surface is an internally reflective surface that is oriented during the step of forming to reflect a laser beam produced within the number of material layers through one or more of the layers and out of a bottom surface of the substrate.

69. The method as recited in claim 68 wherein during the step of forming the wall surface, the internally reflective wall surface of the diode laser is oriented so that the laser beam produced within the diode laser exits the laser at a 90 degree angle relative to the substrate bottom surface.

70. The method as recited in claim 68 wherein during the steps of forming the number of material layers, forming a gain layer that is interposed between the P-type material layer and the N-type material layer.

71. The method as recited in claim 68 wherein during the steps of forming the number of material layers, forming a diffraction grating feedback layer adjacent the gain layer.

72. The method as recited in claim 68 wherein the substrate is vicinally oriented an angle of approximately 9.7 degrees from a (100) orientation.

73. The method as recited in claim 68 wherein before the step of forming the number of material layers, forming a recessed section along a surface of the substrate, wherein the number of material layers are deposited adjacent the recessed section.
